(19) United States
(12) Patent Application Publication
(10) Pub. No.: US 2023/0046459 A1
(43) Pub. Date: Feb. 16, 2023

(54) SUBSTRATE PREPARATION CHAMBER WITH SUBSTRATE POSITIONING FEATURES

(71) Applicant: Kateeva, Inc., Newark, CA (US)

(72) Inventors: Karl Andrew Nordhoff, Cupertino, CA (US); Alexander Sou-Kang Ko, Santa Clara, CA (US); Christopher Buchner, Sunnyvale, CA (US)

(73) Assignee: KATEEVA, INC., Newark, CA (US)

(21) Appl. No.: 17/817,767

(22) Filed: Aug. 5, 2022

Related U.S. Application Data
(60) Provisional application No. 63/260,111, filed on Aug. 10, 2021.

(51) Int. Cl. B41J 13/00; B41J 13/10; B41J 29/00

(52) U.S. Cl. CPC B41J 13/0063; B41J 13/10; B41J 29/00

(57) ABSTRACT

A substrate preparation chamber is described herein. The substrate preparation chamber comprises an enclosure, a rotatable substrate support disposed within the enclosure, and an atmosphere replacement system coupled to the enclosure. The substrate preparation chamber can be used with an inkjet printing system, where the substrate preparation chamber is coupled to a printing enclosure such that a door is operable to place the enclosure of the substrate preparation chamber in fluid communication with the printing enclosure.

### CROSS-REFERENCE TO RELATED APPLICATIONS

This patent application claims benefit of U.S. Provisional Patent Application Ser. No. 63/260,111 filed Aug. 10, 2021, which is entirely incorporated herein by reference.

### FIELD

Embodiments described herein relate to substrate handling for industrial inkjet printers. Specifically, apparatus and methods are described herein for changing orientation of substrates for processing and delivering multiple substrates concurrently for individual processing in inkjet printing systems.

### BACKGROUND

Industrial inkjet printers are used to apply materials to large substrates to form devices of all kinds. The substrates can be rigid or flexible, thick or thin, and can be made of an array of materials. The most common types of substrates used in this way are substrates made of various types of glass, which are processed to make electronic displays such as televisions and displays for smart phones.

Such displays are typically made on a large sheet of glass, with many devices mapped out on the sheet. Making multiple devices in one processing pass achieves economy of scale, reducing the unit price of the individual devices. There is a continuing need to enlarge the processing format for display manufacture, which also applies to manufacture of other electronic devices on other substrates.

As the form factor of display panels grows, the space for fabrication equipment grows dear, and manufacturers seek ways to optimize the footprint of such equipment. Improvements in flexibility of substrate handling can help.

### SUMMARY

Embodiments described herein provide a substrate preparation chamber, comprising an enclosure; a rotatable substrate support disposed within the enclosure; and an atmosphere replacement system coupled to the enclosure.

Other embodiments described herein provide an inkjet printing system, comprising an inkjet printer disposed within a printing enclosure; and a substrate preparation chamber coupled to the printing enclosure, the substrate preparation chamber comprising a preparation enclosure with two or more doors; a rotatable substrate support disposed within the preparation enclosure; and an atmosphere replacement system coupled to the preparation enclosure, wherein at least one of the doors is operable to place the preparation enclosure and the printing enclosure in fluid communication.

Other embodiments described herein provide a method of processing a substrate, comprising disposing the substrate on a rotatable substrate support of a substrate preparation chamber; replacing the atmosphere within the substrate preparation chamber with an inert atmosphere; rotating the substrate to an output orientation within the substrate preparation chamber; and transferring the substrate to a printing system using a substrate handler.

### BRIEF DESCRIPTION OF THE FIGURES

FIG. 1 is a plan view of a printing system according to one embodiment.

FIGS. 2A-2D are activity diagrams showing operation of a substrate preparation chamber having substrate rotation and lateral movement capability, according to one embodiment.

FIG. 2E is a plan view of a substrate support of the substrate preparation chamber of FIGS. 2A-2D, according to one embodiment.

FIG. 3 is a schematic elevation view of a substrate preparation chamber according to one embodiment.

FIG. 4 is a flow diagram summarizing a method according to one embodiment.

### DETAILED DESCRIPTION

A load lock chamber is described herein that has substrate positioning features, including rotation and optionally lateral translation capabilities. An inkjet printing system that uses such a load lock chamber is also described, along with methods enabled by such equipment.

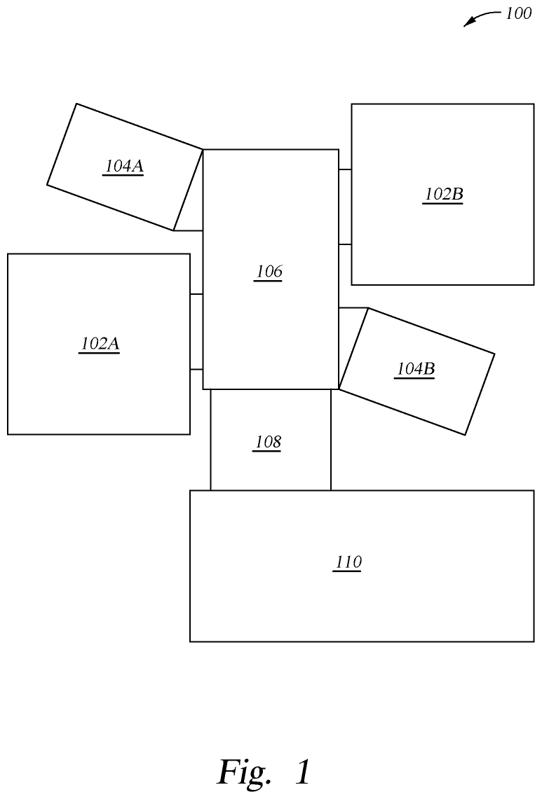

FIG. 1 is a view of an inkjet printing system 100 according to one embodiment. The inkjet printing system 100 includes at least one inkjet printer 102. Here there are two inkjet printers, 102A and 102B. The inkjet printing system 100 also includes at least one processing chamber 104. Here there are two processing chambers 104A and 104B. The inkjet printer 102 is for depositing a material on a substrate, and the processing chamber 104 is for processing the deposited material. Here, the processing chambers 104A and 104B are UV chambers for irradiating the deposited material, but the processing chamber or chambers could be thermal chambers, cooling chambers, or other processing chambers. The processing chambers 104 could be different. For example, the processing chamber 104A could be a UV processing chamber while the processing chamber 104B could be a thermal processing chamber. A substrate handling chamber 106 is coupled to the inkjet printer 102 and the processing chamber 104, in this case to the two inkjet printers 102A and 102B and the two processing chambers 104A and 104B. The substrate handling chamber 106 has a substrate handler that deposits and retrieves substrates in the processing chambers 104A and 104B and the printers 102A and 102B. The substrate handler is movably attached to a track by a rotatable support that enables the substrate handler to move linearly within the substrate handling chamber 106. The rotatable support can rotate the substrate handler to orient the substrate handler to enter any of the chambers 102A, 102B, 104A, and 104B.

A substrate preparation chamber 108 is coupled to the substrate handling chamber 106. The substrate preparation chamber 108 has the capability to rotate substrates to provide substrates in a desired orientation, for example portrait or landscape orientation. The rotation takes place within the substrate preparation chamber 108. The substrate preparation chamber 108 also, optionally, has the capability to translate substrates within the substrate preparation chamber 108 to position substrates for retrieval by one or more substrate handlers. Here, although not visible in this plan view, there are two substrate preparation chambers 108 in a stacked configuration to provide input and output handling for the printing system 100. The rotatable substrate support that couples the substrate handler to the track within the substrate handling chamber 106 can have z-motion capability, for example a telescoping stand, to access the two stacked substrate preparation chambers 108 to retrieve substrates from, and deposit substrates to, the stacked substrate preparation chambers 108. The substrate preparation chamber 108, or both the chambers 108, are typically coupled to a substrate delivery chamber 110 that delivers substrates to the substrate preparation chamber 108, or one of the chambers 108, and retrieves substrate from one or more of the chambers 108. The capability of the substrate preparation chambers 108 to rotate substrates within the chambers 108 enables the substrate delivery chamber 110 to handle substrates in a different orientation from the printing system 100, if necessary. Atmosphere replacement hardware is coupled to the substrate preparation chamber 108, or more than one of the chambers 108 if there are multiple such chambers. The atmosphere replacement hardware (not shown) generally includes one or more vacuum pumps to remove a first atmosphere from the interior of the chamber 108, and a source of a second atmosphere to provide the second atmosphere to the chamber 108. In one case, an ambient atmosphere is removed and an inert, or otherwise non-reactive, atmosphere is substituted to prepare a substrate for processing in the printing system 100. In another case, an atmosphere containing process chemicals arising from processing of substrates in the printing system 100 is removed and replaced by a clean atmosphere to avoid transmitting process gases to the substrate delivery chamber 110.

In an alternate version, rather than having two stacked substrate preparation chambers 108 for substrate input and output at one location of the system 100, one substrate preparation chamber 108 can be located at an input location of the system 100, as schematically shown in the plan view of FIG. 1, and another substrate preparation chamber 108 can be located at an output location of the system 100, for example at an end of the substrate handling chamber 106 opposite from the end coupled to the substrate preparation chamber 108 in FIG. 1. Such configurations can be useful to increase throughput in a processing system. In other cases, such a configuration can be used to transfer substrates in pairs from a first processing system directly to a second processing system with a substrate handler configured to retrieve paired substrates from a substrate preparation chamber such as the chamber 108.

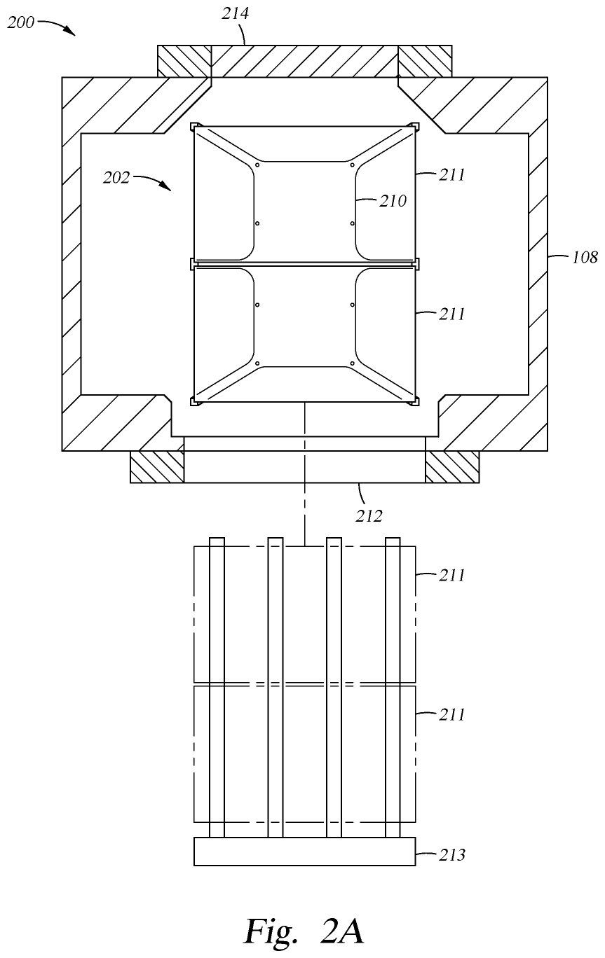

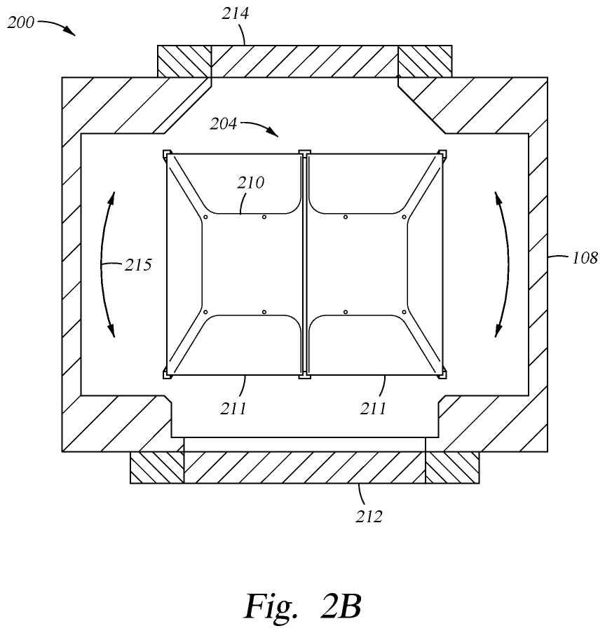

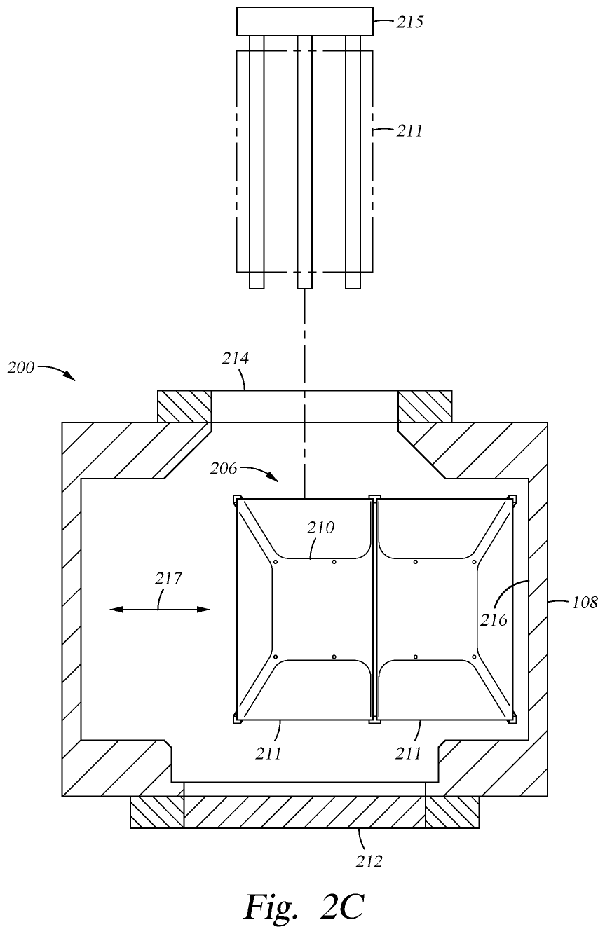

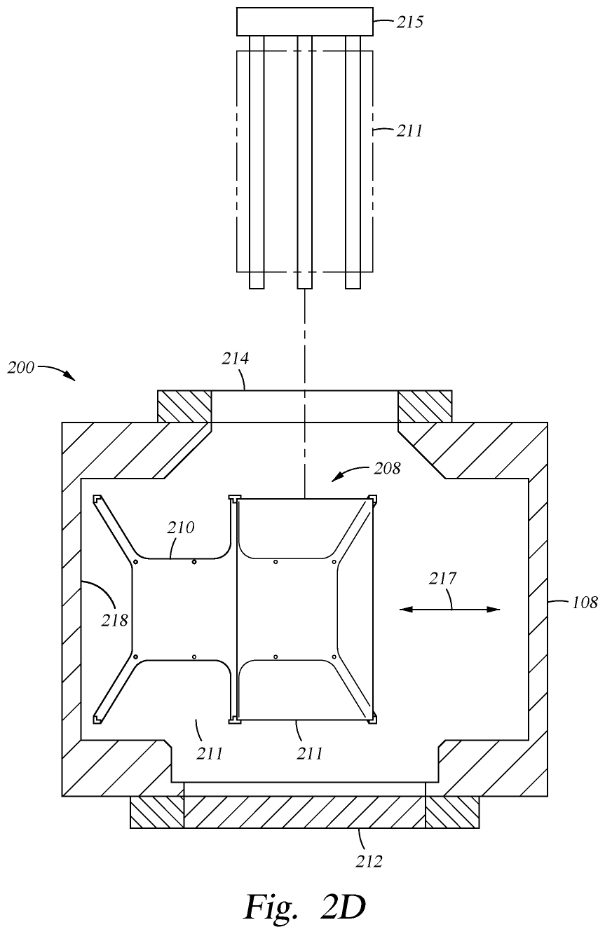

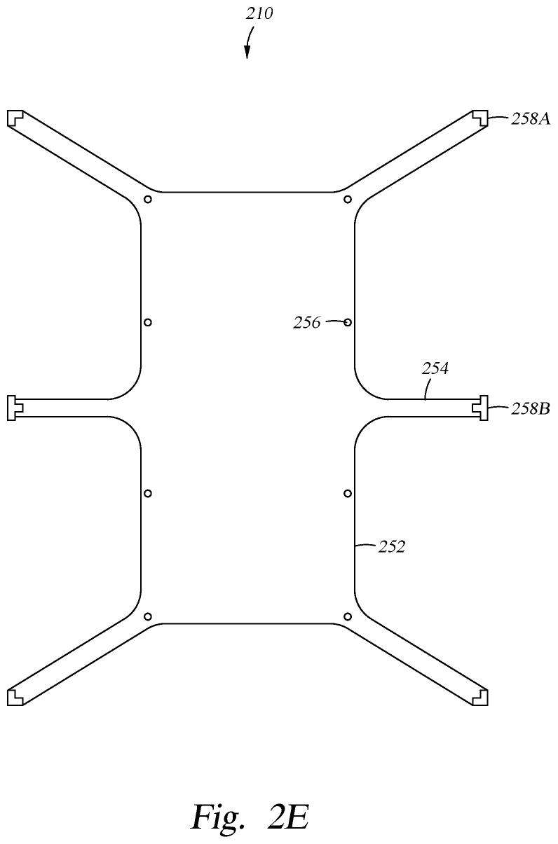

As noted above, the substrate preparation chamber 108 has the capability to rotate a substrate in order to provide the substrate in a desired orientation to the printing system 100. In one case, the substrate delivery chamber 110 has a substrate handler that can deliver more than one substrate at once in the landscape configuration while the substrate handling chamber 106 has a substrate handler that can retrieve only one substrate at a time in the portrait orientation. FIG. 2A is an activity diagram showing loading of substrates into the substrate preparation chamber 108. The substrate preparation chamber 108 is shown in a substrate receiving orientation 202. In the substrate receiving orientation 202, a substrate support 210 is positioned to receive one or more substrates, in this case two substrates, to be placed side-by-side on the substrate support 210. The substrate support 210 has two substrate locations for receiving two substrates 211 in portrait orientation simultaneously. A first door 212 of the substrate preparation chamber 108 is open to pass the substrates. In this case, the substrates are delivered in landscape orientation, so the first door 212 is sized to permit passage of landscape orientation substrates through the first door 212. A delivery handler 213 is shown in position to deliver two substrates, side by side in a landscape orientation, to the substrate preparation chamber 108 in the substrate receiving orientation 202. The substrate support 210 is configured with edge contacts to support substrates along an edge thereof while providing tolerance for z-movement of the substrate handler 213.

FIG. 2B is an activity diagram showing the substrate 211 after loading into the substrate preparation chamber 108. The substrate support 210 is mounted on a rotation support (not shown) that can rotate the substrate support 210. Here, the substrates 211 are shown in a rotated orientation 204. In the rotated orientation 204, the substrate support 210 has rotated 90 degrees, as denoted by rotation arrow 215. The interior of the substrate preparation chamber 108 is contoured to provide freedom of rotation and translation of substrates within the interior. The first door 212 is closed to permit safe operation of the substrate positioning capabilities of the substrate preparation chamber 108. The substrates are now positioned in a portrait orientation for retrieval through a second door 214, which is closed in the rotated orientation 204.

FIG. 2C is an activity diagram showing the substrate preparation chamber 108 in preparation for retrieval of the substrates 211 for processing. The substrate support 210 is shown here in a first translated orientation 206. In the first translated orientation 206, the substrate support 210 has moved to a first side 216 of the substrate preparation chamber 108, as denoted by side-to-side arrow 217, to provide access to one substrate disposed on the substrate support 210. The second door 214 is open to provide access to a substrate. The second door 214 is narrower than the first door 212 because the second door 214 provides access for a substrate to pass through in portrait orientation after passing through the first door 212 in landscape orientation.

FIG. 2D is an activity diagram showing the substrate preparation chamber 108 in the process of substrate retrieval for processing. The substrate support 210 is shown here in a second translated orientation 208. The first substrate is shown in phantom supported by a substrate handler 215, which is configured to handle substrates in the portrait orientation, having retrieved the first substrate while the substrate support 210 was in the first translated orientation 206, as shown in FIG. 2C. The substrate handler 215 could be located in the substrate handling chamber 106 of FIG. 1. The substrate handler 215, housed in the substrate handling chamber 106, would have translated along the track therein to a location for accessing the substrate preparation chamber 108, and would have rotated to the orientation shown here to enter the substrate preparation chamber 108.

In the second translated orientation 208 shown here, the substrate support 210 has moved to a second side 218 of the substrate preparation chamber 108, as denoted by side-to-side arrow 217, to provide access to a second substrate disposed on the substrate support 210. In the views of the first and second translated orientations, the substrate handler 215 is poised to access the interior of the substrate preparation chamber 108 to retrieve a substrate. Because the substrate support 210 has moved laterally, the substrate handler 215 can access one or the other substrate disposed on the substrate support 210.

The rotation and optional translation capabilities of the substrate preparation chamber 108 can be used to position substrates in any convenient orientation for input or output while concurrently preparing an atmosphere inside the substrate preparation chamber for non-disruptive interface with another atmosphere inside an adjacent chamber coupled to the substrate preparation chamber. While the substrate is in motion, rotating or translating within the substrate preparation chamber, vacuum pumps can be engaged to remove the first atmosphere and the source of second atmosphere can be engaged to replace the first atmosphere with a second atmosphere. In some cases, motion, vacuum pumping, and second atmosphere sourcing can all three be active at the same time.

FIG. 2E is a plan view of the substrate support 210 of FIGS. 2A-2D. The substrate support 210 has a central portion 252 and a plurality of arms 254 extending laterally outward from the central portion 252. Here, the central portion 252 has a generally rectangular shape, and there are six arms 254 extending laterally outward, two along a short middle axis of the central portion 252, and four from the corners of the central portion 252, generally at angles selected to accommodate desired substrate sizes. The substrate support 210 can carry two substrates side by side. The central portion 252 has a plurality of substrate contact bodies 256, which are round pins or posts. Each of the arms has an edge contact body 258. Four of the edge contact bodies 258 are single-corner contact bodies 258A. The single-corner contact bodies 258A are angled protrusions attached to the ends of the arms 254 that extend from the corners of the central portion 252. Two of the edge contact bodies 258 are double-corner contact bodies 258B. The double-corner contact bodies 258B are attached to the ends of the arms 254 that extend along the short middle axis of the central portion 252. The edge contact bodies 258 of the substrate support 210 provide support in the opposite direction of gravity for securing substrates vertically, and provide lateral support by capturing substrates along an outer edge of the substrates to prevent shifting of substrates on the support 210 when the support 210 is moved according to the description herein.

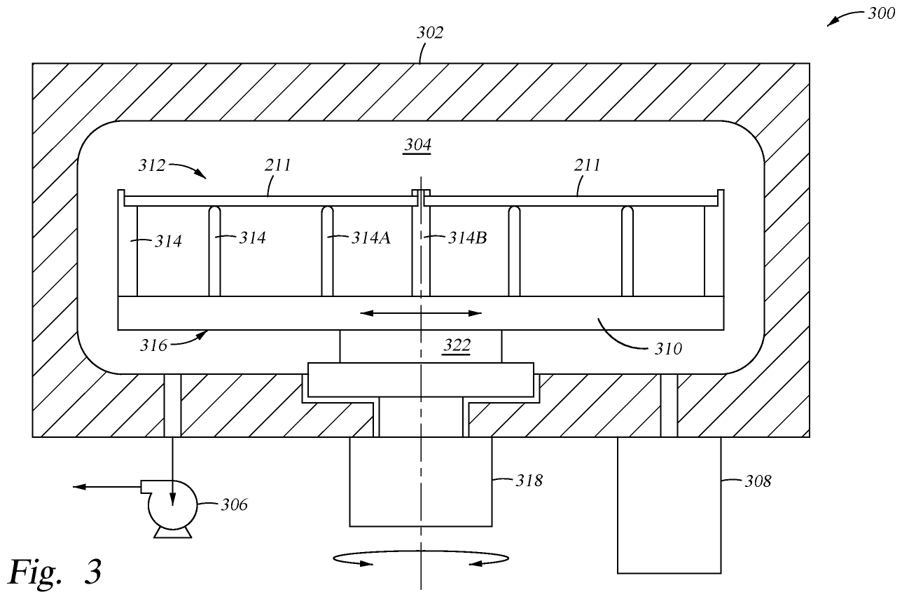

FIG. 3 is a schematic elevation view of a substrate preparation chamber 300 according to one embodiment. The substrate preparation chamber 300 has an enclosure 302 that defines an interior 304 of the substrate preparation chamber 300. The enclosure 302 separates the atmosphere of the interior 304 from an atmosphere outside the enclosure 302. One or more vacuum pumps 306, for example roughing pumps and/or turbo pumps, are coupled to the enclosure 302 at an exterior thereof, where one or more ports (not shown) are provided to allow fluid communication of the one or more vacuum pumps with the interior 304 of the enclosure 302. A source 308 of atmospheric gases is fluidly coupled with the interior 304 to provide replacement atmosphere to the interior 304. The source 308 may include inert gases such as noble gases and non-reactive gases such as nitrogen, hydrogen, and the like that are non-reactive with substrates and deposited materials, pressure control, and temperature control to provide a controlled atmosphere within the interior 304.

The one or more vacuum pumps 306 and the source 308 may be operated concurrently to provide gas flow through the interior 304, for example in a purging operation, and/or sequentially to replace the atmosphere within the interior 304 as expeditiously as possible. In one method, a vacuum pump 306 is activated to lower a pressure within the interior 304. Pressure in the interior 304 is monitored, and when the pressure reaches a target, gas flow from the source 308 is activated to flow a second atmosphere of gas into the interior 304. At that time, or at a time thereafter, the vacuum pump 306 can be deactivated, or a bypass (not shown) can be activated to decouple the vacuum pump 306 from the interior 304, and the source 308 can be allowed to flow into the interior 304, thus boosting pressure in the interior 304 and diluting the gases of the first atmosphere. When pressure reaches a second target, flow of gas from the source 308 can be discontinued and the vacuum pump 306 reactivated or recoupled to the interior 304 to reduce the pressure. Such interaction of the vacuum pump 306 and the source 308 can be pursued in cycles to reduce concentration of first-atmosphere gases in the interior 304 to an acceptable target level before the interior 304 is fluidly coupled to another environment.

A substrate support 310 is disposed in the interior 304. The substrate support 310 has a substrate support side 312 that generally contacts substrates disposed on the substrate support 310. In this case, the substrate support side 312 features a plurality of substrate contacts 314 that extend away from the substrate support side 312 to provide support with minimal contact. The substrate contacts 314, here, are two types, central contacts 314A that are posts with rounded tips that contact the lower surface of the substrate, and outer contacts 3148, posts with edge or corner capture members that contact the edge or corner of the substrate. The posts may be made of any suitable material to provide secure support for substrates. Ceramic, plastic, and metal can be used. The rounded tips of the central contacts 314A, and the capture members of the outer contacts 314B, are generally made of a material suitable for substrate contact, and may be configured to provide a friction contact to prevent substrates from shifting during movement of the substrate support 310. In one case, the rounded tips are made of a polymeric material, such as polyether ether ketone (PEEK). Where more secure support might be desired, the tips of the posts may be provided with contact pads that have vacuum ports to apply suction between the posts and the substrate. The vacuum ports can be fluidly connected to suction by conduits (not shown) within the posts. In other cases, rather than posts, the substrate contacts 314 may be spherical protrusions or flat pads.

The substrate contacts 314 are attached to a support body 316 that rests on a rotary actuator 318, which may include a ball bearing or roller bearing track, or another rotational bearing, along with a driver to provide rotational force. While one or more substrates are disposed on the substrate contacts 314, the rotational actuator 318 can be activated to move the support body 316 to rotate the substrates within the interior 304 of the substrate preparation chamber 300. The rotary actuator 318 may couple to the support body 316 using any convenient coupling, such as a circular or linear gear to couple to teeth at the side or bottom of the support body 316.

An optional linear motion system 322 can be coupled to the substrate support 310 to provide translation capability within the substrate preparation chamber 300. The linear motion system 322 is shown here coupled to the support body 316, and the rotary actuator 318 is shown in configuration to rotate the linear motion system 322 along with the substrate support 310. The couplings can be reversed, where the rotary actuator 318 is coupled to the support body 316 and supported on the linear motion system 322. The linear motion system 322 can include any convenient type of linear actuator, such as a screw type or gear type actuator. The rotary actuator 318 and the linear motion system 322 can be operated concurrently, such that the support body 316 moves in a complex linear-rotary motion, or sequentially. The rotation and translation capabilities of the substrate preparation chamber 300 provide flexibility in positioning and orienting substrates for input to and output from a processing system such as the printing system 100 of FIG. 1. For example, where spacing constraints might require certain orientations and configurations of processing equipment, the rotational and linear positioning capabilities of the substrate preparation chamber 300 can be used to position and orient substrates for angled access by a substrate handler. The substrate handler can enter the substrate preparation chamber 300 at an angle, and the substrate support can rotate the substrates to match the angle of the substrate handler and position the substrates precisely to smoothly engage with the substrate handler.

The substrate preparation chamber 300 has integral rotational and lateral substrate motion within the chamber 300. As such, multiple such chambers can be configured in a stacked configuration, and can move independently from each other. Thus, as in FIG. 1, two such chambers can be stacked, one above the other, and used for independent input and output of substrates from the printing system 100. One chamber can be in one rotational and translational position while the other chamber is in a different rotational and translation position. The substrate supports in the two chambers can move independently, where one moves in a first way at a first time and the other moves in a second way at a second time.

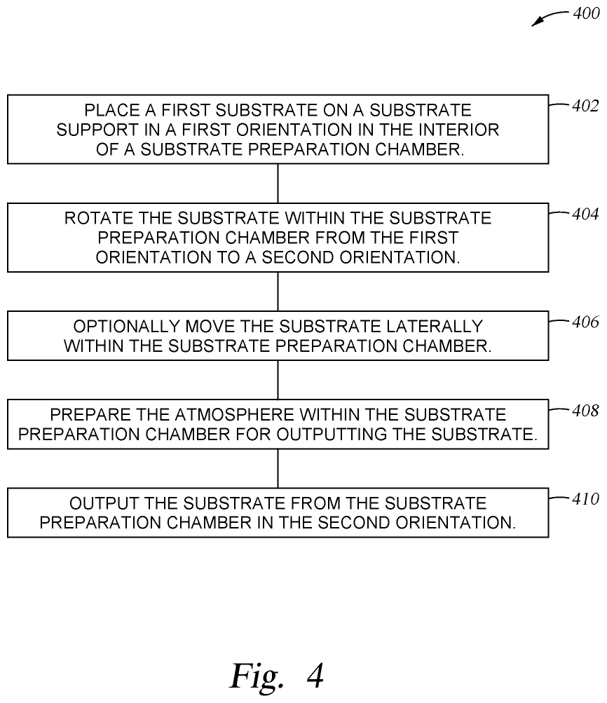

FIG. 4 is a flow diagram summarizing a method 400 according to one embodiment. The method 400 is a method of handling substrates in a processing system. At 402, a substrate is placed on a substrate support in a first orientation in the interior of a substrate preparation chamber. The substrate is typically placed on the substrate support using a substrate handler, for example a robot with an end-effector configured to access the interior of the chamber and fit between substrate contact bodies of the substrate support that protrude away from a support body of the substrate support to form spaces between the substrate contact bodies. The end-effector typically fits between the substrate contact bodies to place the substrate on the contact bodies, after which the end-effector disengages from the substrate and withdraws. In some cases, a single substrate handler might place two or more substrates, positioned side by side, on the substrate support simultaneously in one motion.

At 404, the substrate support is rotated within the substrate preparation chamber to rotate the substrate, or substrates if there is more than one. Rotation of the substrate support rotates the substrate from the first orientation, in which the substrate was initially placed on the substrate support, to a second orientation different from the first orientation. For example, the first orientation might be considered a “portrait” orientation while the second orientation is considered a “landscape” orientation, or vice versa. Rotating the substrate enables the substrate to be accessed in different orientations by different substrate handlers. For example, a first substrate handler might be configured to interact with substrates in the portrait orientation while a second substrate handler is configured to interact with substrate in the landscape orientation. Rotation of the substrate in the substrate preparation chamber allows one substrate preparation chamber to interact with substrate handlers in two different orientations, in this case two orthogonal orientations.

At 406, the substrate support is optionally moved laterally within the substrate preparation chamber. Moving the substrate support laterally can align the substrate, or if more than one substrate is placed on the substrate support side-by-side, substrates with a substrate handler to be accessed by the handler. For example, if the substrate is not aligned with an access doorway of the substrate preparation chamber, moving the substrate support laterally can align the substrate with the access doorway. Where more than one substrate is placed on the substrate support, moving the substrate support laterally can align a first substrate with the access doorway, and after the first substrate is removed from the substrate preparation chamber, can align a second substrate with the be access doorway to be removed sequentially by the same substrate handler. In this regard, the substrate support can be moved laterally any number of times to provide access to multiple substrates in different positions. If only one substrate is to be placed in the substrate preparation chamber, moving the substrate support laterally can position the substrate support optimally to receive the substrate as input and to deliver the substrate as output.

At 408, the atmosphere within the substrate preparation chamber is prepared for outputting the substrate. A gas mixture is flowed through the interior of the substrate preparation chamber to prepare the atmosphere. The interior of the substrate preparation chamber may also be pumped down to remove undesired atmosphere from the chamber. Flowing the gas mixture and pumping the chamber can be performed in any sequence or combination to optimize the time required to prepare the atmosphere, and preparation of the atmosphere can be performed before, during, or after any of rotating the substrate support and moving the substrate support laterally.

At 410, the substrate is output from the substrate preparation chamber in the second orientation. Because the atmosphere within the substrate preparation chamber has been prepared for outputting the substrate, when the substrate preparation chamber opens to output the substrate, the atmosphere released from the chamber interior is not disruptive to any connected or ambient environment. The method 400 can used in connection with providing substrates to a processing system for processing and in connection with retrieving substrates from a processing system after processing.

The methods and apparatus described herein can be used to deliver a substrate to a processing system in a first orientation, process the substrate in a second orientation different from the first orientation, and deliver the processed substrate for recovery in the first orientation. The first and second orientations can be orthogonal, or can be angled to any extent. Such capabilities can be used where, for example, an indexing robot delivers one or more substrates in landscape orientation to an inkjet printing system that processes substrates in portrait orientation. The substrate preparation chamber described herein can receive the substrates in landscape orientation, one at a time or more than one at a time, rotate the substrates to portrait orientation for delivery to the printing system, and provide access to a portrait orientation robot to retrieve the substrates, one at a time if there is more than one substrate in the substrate preparation chamber, and deliver the substrates to the printing system for processing. After processing, the portrait orientation robot can retrieve the substrate from the printing system, deliver the substrate to the substrate preparation chamber in portrait orientation, and the substrate preparation chamber can rotate the substrate to landscape orientation for delivery to the indexing robot.

While the foregoing is directed to embodiments of one or more inventions, other embodiments of such inventions not specifically described in the present disclosure may be devised without departing from the basic scope thereof, which is determined by the claims that follow.

1. A substrate preparation chamber, comprising:
an enclosure;
a rotatable substrate support having two substrate locations disposed within the enclosure and a plurality of edge contact bodies; and
an atmosphere replacement system coupled to the enclosure.

2. The substrate preparation chamber of claim 1, further comprising:
a linear actuator coupled to the rotatable substrate support.

3. The substrate preparation chamber of claim 1, wherein the rotatable substrate support comprises a plurality of central substrate contacts having a first portion of the edge contact bodies and a plurality of outer substrate contacts having a second portion of the edge contact bodies.

4. The substrate preparation chamber of claim 3, wherein the central substrate contacts and the outer substrate contacts project from a support body coupled to a rotary actuator.

5. An inkjet printing system, comprising:
an inkjet printer disposed within a printing enclosure; and
a substrate preparation chamber coupled to the printing enclosure, the substrate preparation chamber comprising:
a preparation enclosure with two or more doors;
a rotatable substrate support disposed within the preparation enclosure; and
an atmosphere replacement system coupled to the preparation enclosure, wherein at least one of the doors is operable to place the preparation enclosure and the printing enclosure in fluid communication.

6. The inkjet printing system of claim 5, wherein the substrate preparation chamber further comprises a linear actuator coupled to the rotatable substrate support.

7. The inkjet printing system of claim 6, wherein the substrate preparation chamber is a first substrate preparation chamber, and further comprising a second substrate preparation chamber coupled to the printing enclosure, the second substrate preparation chamber comprising:
a preparation enclosure with two or more doors; and
a rotatable substrate support disposed within the preparation enclosure.

8. The inkjet printing system of claim 7, wherein the second substrate preparation chamber is stacked on the first substrate preparation chamber.

9. The inkjet printing system of claim 8, wherein the preparation enclosure of the second substrate preparation chamber is coupled to the atmosphere replacement system.

10. The inkjet printing system of claim 6, further comprising an inkjet printer disposed within the printing enclosure and a substrate handler disposed within the printing enclosure, the substrate handler comprising a linear actuator and a rotary actuator and configured to retrieve a substrate from the substrate preparation chamber.

11. The inkjet printing system of claim 10, further comprising a substrate delivery chamber configured to deliver two substrates to the substrate preparation chamber simultaneously.

12. The inkjet printing system of claim 11, wherein the substrate delivery chamber is configured to deliver substrates to the substrate preparation chamber in a first orientation and the substrate handler is configured to retrieve a substrate from the substrate preparation chamber in a second orientation different from the first orientation.

13. The inkjet printing system of claim 6, wherein the substrate support is configured to move linearly and to rotate simultaneously.

14. A method of processing a substrate, comprising:
disposing the substrate on a rotatable substrate support of a substrate preparation chamber;
replacing the atmosphere within the substrate preparation chamber with an inert atmosphere;
rotating the substrate to an output orientation within the substrate preparation chamber; and
transferring the substrate to a printing system using a substrate handler.

15. The method of claim 14, further comprising moving the substrate laterally within the substrate preparation chamber.

16. The method of claim 14, wherein the substrate preparation chamber is a first substrate preparation chamber, and further comprising transferring the substrate to the second substrate preparation chamber from the printing system using the substrate handler.

17. The method of claim 14, wherein more than one substrate is concurrently disposed on the rotatable substrate support, and the substrate handler transfers one substrate at a time to the printing system.

18. The method of claim 17, further comprising using a handler of a substrate delivery chamber to dispose more than one substrate on the rotatable substrate support simultaneously.

19. The method of claim 18, wherein the substrate handler retrieves a first substrate and a second substrate from the rotatable substrate support, the first and second substrates concurrently disposed on the rotatable substrate support, and the substrate handler delivers the first substrate to a first inkjet printer of the printing system and delivers the second substrate to a second inkjet printer of the printing system.

20. The method of claim 16, wherein the second substrate preparation chamber is stacked on the first substrate preparation chamber.
